(19) United States
(12) Patent Application Publication
(10) Pub. No.: US 2018/0148833 A1
(43) Pub. Date: May 31, 2018

(54) METHODS FOR DEPOSITING FLOWABLE SILICON CONTAINING FILMS USING HOT WIRE CHEMICAL VAPOR DEPOSITION

(71) Applicant: APPLIED MATERIALS, INC., Santa Clara, CA (US)

(72) Inventors: Sukti CHATTERJEE, Cupertino, CA (US); LANCE SCUDDER, Sunnyvale, CA (US); ERIC H. LIU, San Mateo, CA (US); PRAVIN K. NARWANKAR, Sunnyvale, CA (US); PRAMIT MANNA, Milpitas, CA (US); ABHIJIT MALLICK, Fremont, CA (US)

(21) Appl. No.: 15/800,266

(22) Filed: Nov. 1, 2017

Related U.S. Application Data
(60) Provisional application No. 62/426,384, filed on Nov. 25, 2016.

(51) Int. Cl. C23C 16/448; H01L 21/02; C23C 16/24; C23C 16/32; C23C 16/34; C23C 16/40; C23C 16/56; C23C 16/52

(52) U.S. Cl. CPC C23C 16/448; C23C 16/52; H01L 21/02664; H01L 21/0262; H01L 21/02529; H01L 21/02167; H01L 21/02211; H01L 21/02126; H01L 21/0217; H01L 21/0228; C23C 16/24; C23C 16/325; C23C 16/345; C23C 16/401; C23C 16/56; H01L 21/02532

(57) ABSTRACT

In some embodiments, a method of processing a substrate disposed within a processing volume of a hot wire chemical vapor deposition (HWCVD) process chamber, includes: (a) providing a silicon containing precursor gas into the processing volume, the silicon containing precursor gas is provided into the processing volume from an inlet located a first distance above a surface of the substrate; (b) breaking hydrogen-silicon bonds within molecules of the silicon containing precursor via introduction of hydrogen radicals to the processing volume to deposit a flowable silicon containing layer atop the substrate, wherein the hydrogen radicals are formed by flowing a hydrogen containing gas over a plurality of wires disposed within the processing volume above the substrate and the inlet.

### CROSS-REFERENCE TO RELATED APPLICATIONS

This application claims benefit of U.S. provisional patent application Ser. No. 62/426,384, filed Nov. 25, 2016, which is herein incorporated by reference in its entirety.

### FIELD

Embodiments of the present disclosure generally relate to methods for flowable silicon containing films.

### BACKGROUND

Flowable silicon containing films are often used in semiconductor manufacturing process to provide void free gap fills, low shrinkage rates, high modulus, and high etch selectivity. Flowable silicon containing films are typically formed using a remote plasma system.

Therefore, the inventors have provided improved methods for depositing flowable silicon containing films.

### SUMMARY

Methods for depositing materials on substrates in a hot wire chemical vapor deposition (HWCVD) process are provided herein. In some embodiments, a method of processing a substrate disposed within a processing volume of a hot wire chemical vapor deposition process chamber includes: (a) providing a silicon containing precursor gas into the processing volume, wherein the silicon containing precursor gas is provided into the processing volume from an inlet located a first distance above a surface of the substrate; (b) breaking hydrogen-silicon bonds within molecules of the silicon containing precursor via introduction of hydrogen radicals to the processing volume to deposit a flowable silicon containing layer atop the substrate, wherein the hydrogen radicals are formed by flowing a hydrogen containing gas over a plurality of wires disposed within the processing volume above the substrate and the inlet.

In some embodiments, the disclosure may be embodied in a computer readable medium having instructions stored thereon that, when executed, cause a method to be performed in a process chamber, the method includes any of the embodiments disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. The appended drawings illustrate only typical embodiments of the disclosure and are not to be considered limiting of scope, for the disclosure may admit to other equally effective embodiments.

FIG. 1 depicts a flow chart for a method of depositing flowable silicon containing films in accordance with some embodiments of the present disclosure.

FIG. 2 depicts a schematic side view of a hot wire chemical vapor deposition (HWCVD) process chamber in accordance with some embodiments of the present disclosure.

FIG. 3 shows the reaction process 300 for forming a flowable silicon layer using at least one of a silane, disilane, trisilane, tetrasilane, pentasilane, dodecachlorotetrasilane, or dodecachloropentasilane precursor in accordance with some embodiments of the present disclosure.

FIG. 4A shows the reaction process 400 for forming a flowable silicon carbide layer using a tetravinylsilane precursor in accordance with some embodiments of the present disclosure.

FIG. 4B shows the reaction process 450 for forming a flowable silicon carbide layer using a trisilapentane precursor in accordance with some embodiments of the present disclosure.

FIG. 4C shows the reaction process 470 for forming a flowable silicon carbide layer using two precursor gases in accordance with some embodiments of the disclosure.

FIG. 5A shows the reaction process 550 for forming a flowable nitride layer using a trisilylamine precursor in accordance with some embodiments of the present disclosure.

FIG. 5B shows the reaction process 500 for forming a flowable nitride layer using two precursor gases in accordance with some embodiments of the present disclosure.

FIG. 6 shows the reaction process 600 for forming a flowable silicon oxycarbide layer using at least one of a tetramethoxysilane, tetraethoxysilane trimethyloxysilane, triethoxysilane, tetramethyldisiloxane, tetramethyldisiloxane, octamethylcyclotetrasiloxane precursor in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide hot wire chemical vapor deposition (HWCVD) processing techniques useful for depositing flowable silicon containing films. In one exemplary application, embodiments of the present disclosure may advantageously be used to deposit flowable silicon containing films without ion bombardment of the substrate. Remote plasmas (e.g., a plasma formed outside of the processing chamber) and quasi-remote plasmas (e.g., a plasma formed within the same process chamber as the substrate at a distance from the substrate) form ions that can damage the surface of the substrate. Embodiments of the present disclosure may advantageously be used to deposit flowable silicon containing films via a hot wire chemical vapor deposition (HWCVD) process chamber, which provides a higher concentration of hydrogen radicals to deposit the flowable silicon containing films compared with a remote plasma system. Embodiments of the present disclosure may advantageously also be used to deposit flowable silicon containing films via a hot wire chemical vapor deposition (HWCVD) process chamber, which provides hydrogen radicals that can be used to cure the flowable silicon containing films without the need for additional curing energy, such as via application of ultraviolet (UV) light.

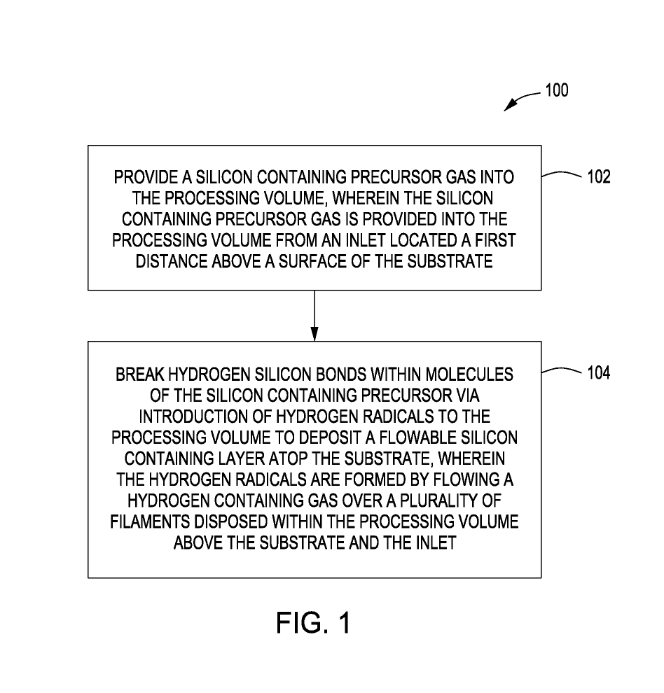

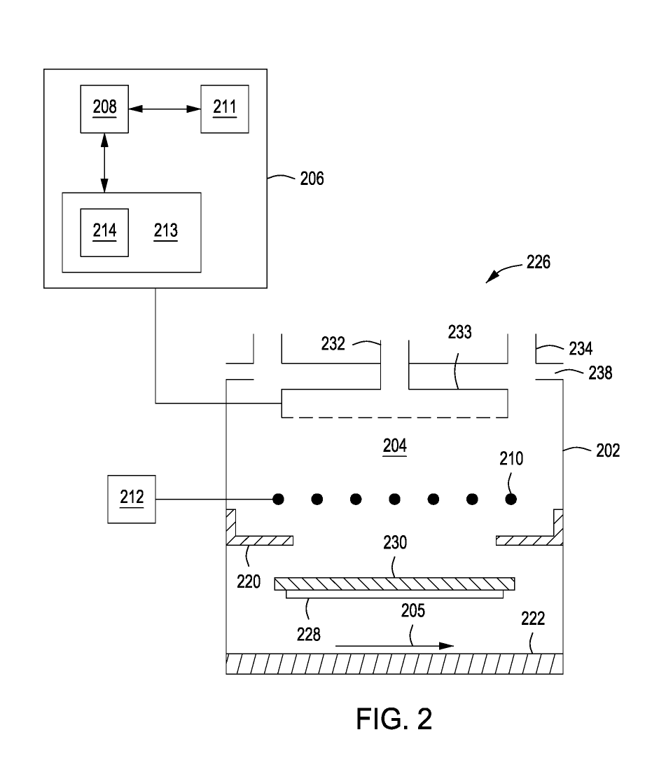

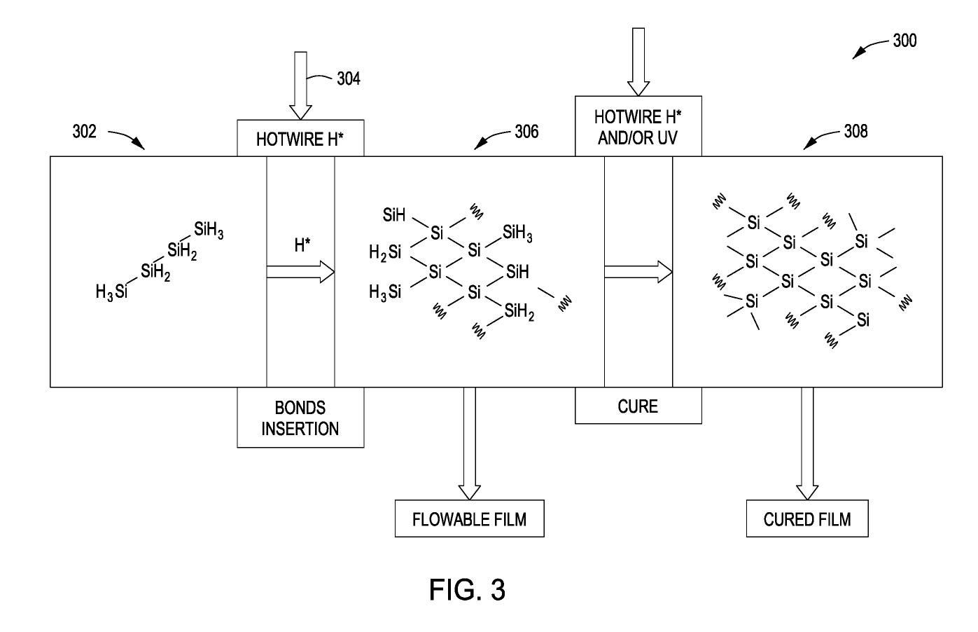

FIG. 1 depicts a flow chart for a method 100 of depositing flowable silicon containing films in accordance with embodiments of the disclosure. Embodiments of the disclosure comprise depositing flowable silicon containing films atop a substrate in a hot wire chemical vapor deposition (HWCVD) process chamber. FIG. 2 depicts a schematic side view of an illustrative substrate processing system used to perform the method of FIG. 1 in accordance with some embodiments of the present disclosure. Any of the embodiments of FIGS. 3-7 may be manufactured by the method 100 and/or the substrate processing system of FIG. 2.

The method 100 begins at 102 by providing a silicon containing precursor gas into the processing volume, wherein the silicon containing precursor gas is provided into the processing volume from an inlet located a first distance above a surface of the substrate.

The substrate may be any suitable substrate, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate may be a semiconductor wafer (e.g., a 200 mm, 300 mm, or the like silicon wafer). In some embodiments, the substrate may include additional semiconductor manufacturing process layers, such as dielectric layers, metal layers, and/or the like. In some embodiments, the substrate may be a partially fabricated semiconductor device such as Logic, DRAM, or a Flash memory device. In addition, features, such as trenches, vias, or the like, may be formed in one or more layers of the substrate.

The silicon containing precursor gas provided to the processing volume depends on the flowable silicon containing layer to be deposited. The flowable silicon containing layer is at least one of pure silicon (Si) (e.g., a layer consisting of, or consisting essentially of, silicon), silicon oxycarbide (SiOC), silicon carbide (SiC), silicon nitride (SiN), or silicon oxynitride (SiON).

In embodiments where the flowable silicon containing layer is pure silicon (Si), the silicon containing precursor gas is at least one of a silane, disilane, trisilane, tetrasilane, pentasilane, dodecachlorotetrasilane, or dodecachloropentasilane gas. In embodiments where the flowable silicon containing layer is silicon oxycarbide (SiOC), the silicon containing precursor gas is at least one of a tetramethoxysilane, tetraethoxysilane trimethyloxysilane, triethoxysilane, tetramethyldisiloxane, tetramethyldisiloxane, or octamethylcyclotetrasiloxane gas. In embodiments where the flowable silicon containing layer is silicon carbide (SiC), the silicon containing precursor gas is trisilapentane or tetravinylsilane gas. In embodiments where the flowable silicon containing layer is silicon nitride (SiN), the silicon containing precursor gas is at least one of trisilylamine, silane, disilane, or trisilane, and at least one of ammonia and/or nitrogen gas. Additional precursors, optionally, can be mixed and delivered with the silicon containing precursor gas. Alternatively, additional precursors can be added through one or more inlets to modulate a final film stoichiometry. Embodiments according to the disclosure include adding a carbon or silicon containing molecule to generate SiC having an adjustable Si:C ratio. Embodiments according to the disclosure include adding a nitrogen or silicon containing molecule to generate SiN having an adjustable Si:N ratio.

The flow rate of the silicon containing precursor gas is about 100 to about 1000 mg/min.

Formation of a flowable silicon containing film depends on the temperature of the substrate during the deposition process and the distance (i.e., a first distance) above the substrate surface at which the silicon containing precursor gas is introduced to the processing volume. Additional process control elements comprise combinations of variations to chamber pressure, initiator flux, monomer flow, and/or a monomer:initiator ratio(s). A temperature of the substrate is about −50 to about 150 degrees Celsius.

The silicon containing precursor gas is introduced to the processing volume through an inlet disposed about 10 to about 50 mm above the surface of the substrate. In some embodiments, where the flowable silicon containing layer is pure silicon (Si) and the silicon containing precursor gas is silane (SiH₄), disilane (Si2H₆), trisilane (Si₃H₅), tetrasilane (Si₄H₁₀), pentasilane (Si₅H₁₂), dodecachlorotetrasilane (Si₄Cl₁₀), or dodecachloropentasilane (Si₆Cl₁₂), the inlet is disposed about 10 to about 50 mm above the surface of the substrate. In embodiments where the flowable silicon containing layer is silicon oxycarbide (SiOC) and the silicon containing precursor gas is at least one of tetramethoxysilane (TMOS), tetraethoxysilane (TEOS), trimethyloxysilane (TriMOS), triethoxysilane (TriEOS), tetramethyldisiloxane (TMDSO), hexamethoxydisilazoxane (HMDS-H) or octamethylcyclotetrasiloxane (OMCTS), the inlet is disposed about 10 to about 50 mm above the surface of the substrate. Embodiments of the disclosure that deposit flowable Si may further comprise a conversion step that converts Si to SiO (oxygen plasma or thermal annealing) SiC, or SiON. Embodiments of the disclosure that deposit flowable Si may further comprise a conversion step that converts Si to SiN. Embodiments of the disclosure that convert Si to SiN may use decoupled plasma nitridation (DPN) technologies. In embodiments of the disclosure where the flowable silicon containing layer is silicon carbide (SiC) and the silicon containing precursor gas is trisilapentane or tetravinylsilane, or a gas mixture of silane, disilane, trisilane tetrasilane, pentasilane, dodecachlorotetrasilane, or dodecachloropentasilane and at least one of methane, propane, trisilapentane or tetravinylsilane, the inlet is disposed about 10 to about 50 mm above the surface of the substrate. In embodiments of the disclosure where the flowable silicon containing layer is silicon nitride (SiN) and the silicon containing precursor gas is trisilylamine or a gas mixture of silane, disilane, trisilane, tetrasilane, pentasilane, dodecachlorotetrasilane, or dodecachloropentasilane and at least one of trisilylamine or ammonia, the inlet is disposed 10 to about 50 above the surface of the substrate.

Next, at 104, hydrogen-silicon bonds within molecules of the silicon containing precursor are broken via introduction of hydrogen radicals to the processing volume to deposit a flowable silicon containing layer atop the substrate. As used herein a flowable silicon-containing film refers to a silicon containing film that is deposited within a feature on a substrate in a “bottom-up” manner (i.e., the film fills the feature from the bottom of the feature to the top of the feature without forming a void within the film material deposited in the feature. The hydrogen radicals are formed by flowing a hydrogen containing gas over a heated plurality of wires disposed within the processing volume above or below the substrate and the inlet. The temperature of the heated plurality of wires is about 1300 to about 2400 degrees Celsius. In some embodiments, a flow rate of the hydrogen containing gas is about 10 to about 1000 sccm.

In some embodiments, the hydrogen containing gas is hydrogen (H₂) gas, ammonia (NH₃) gas, or a combination thereof. In some embodiments, where the hydrogen containing gas is ammonia (NH₃) gas or a combination of ammonia (NH₃) gas and hydrogen (H₂) gas, the hydrogen-silicon bonds within molecules of the silicon containing precursor are broken via introduction of hydrogen radicals and ammonia (NH₃) radicals (e.g., NH, NH₂) to the processing volume. The flow rate of the hydrogen containing gas is about 10 to about 1000 standard cubic centimeters per minute (sccm).

FIG. 3 shows the reaction process 300 for forming a flowable silicon layer using at least one of a silane, disilane, trisilane, tetrasilane, pentasilane, dodecachlorotetrasilane, or dodecachloropentasilane precursor or mixtures thereof. As depicted, a tetrasilane precursor 302 is exposed to hydrogen radicals 304 from a hotwire source. The energy of the hydrogen radicals breaks the hydrogen-silicon bonds in the tetrasilane precursor 302 resulting in flowable silicon film 306. As discussed further below, the flowable silicon film 306 can be cured via the energy of the hydrogen radicals and/or exposure to ultra-violet (UV) light and/or thermal annealing to form a cured silicon film 308. Embodiments of the disclosure include using exposure to ultra-violet (UV) light and/or rapid thermal annealing. The flowable silicon film 306 is optionally cured or densified after deposition has been completed. Curing and/or densification via ultra-violet (UV) light and/or rapid thermal annealing can improve film parametrics, such as density, wet etch rate, and/or compatibility using down-stream device processing.

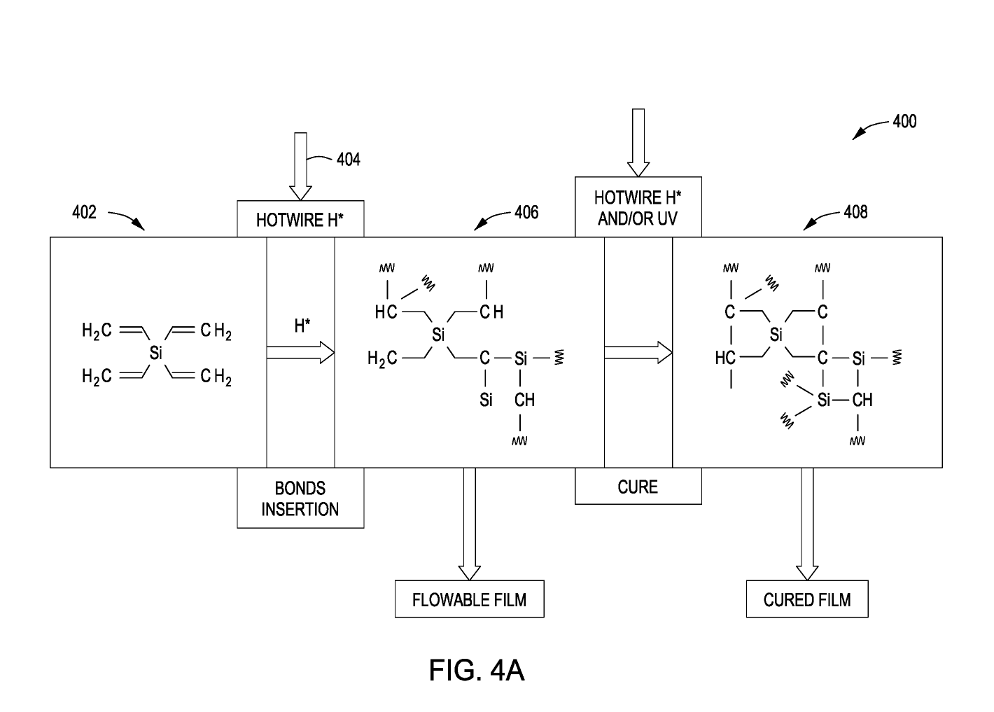

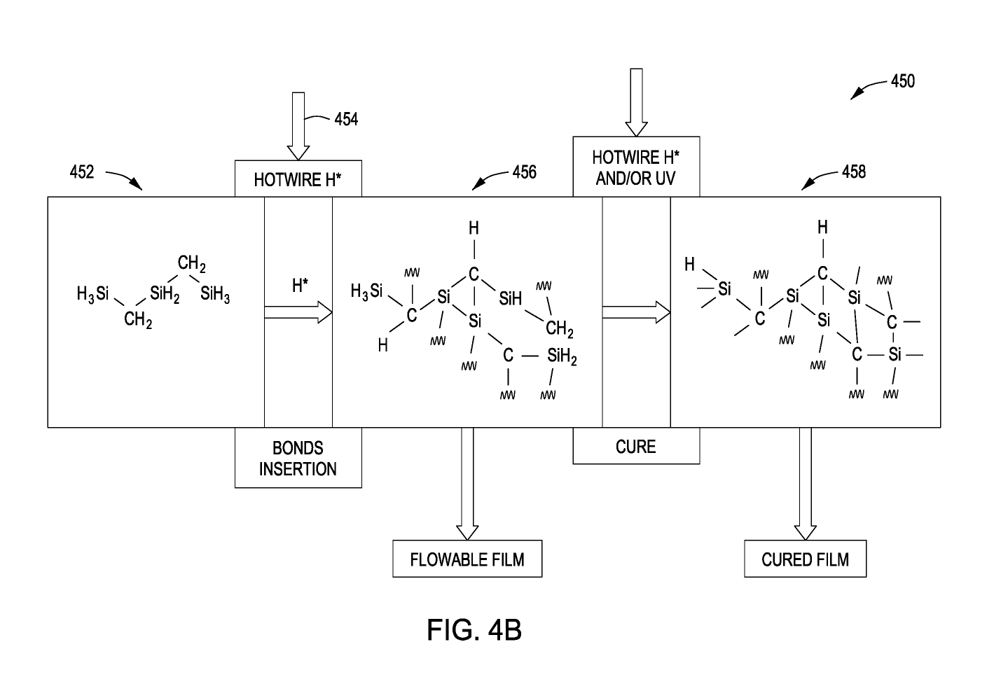

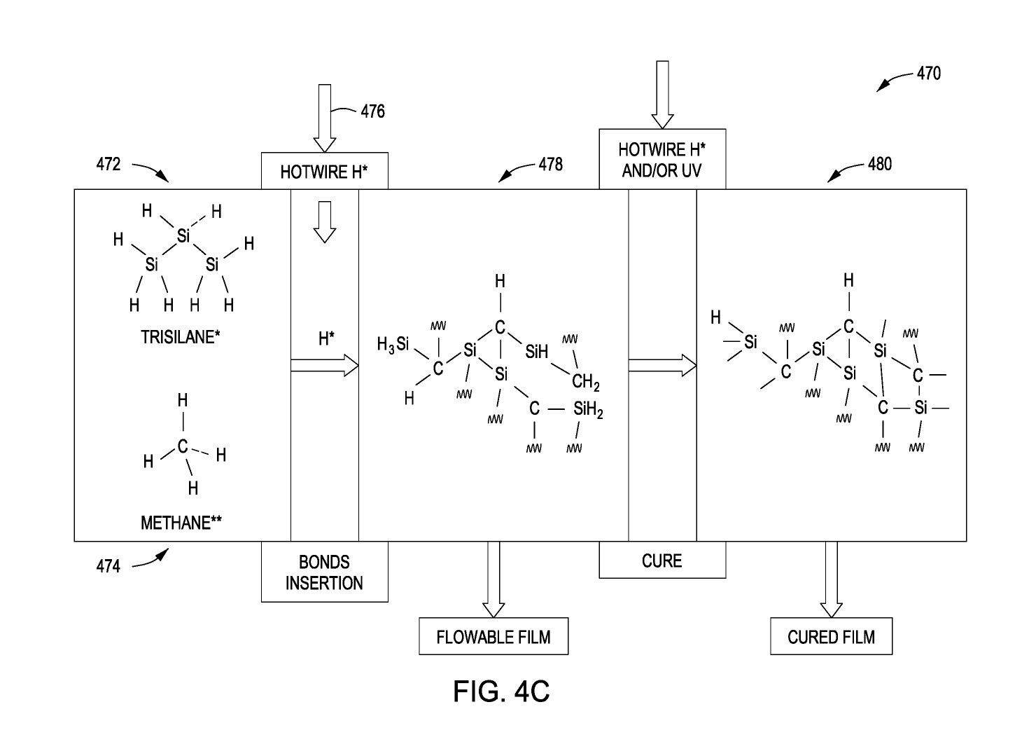

FIG. 4A shows the reaction process 400 for forming a flowable silicon carbide layer using a tetravinylsilane precursor. The tetravinylsilane precursor 402 is exposed to hydrogen radicals 404 from a hotwire source. The energy of the hydrogen radicals breaks the bonds between hydrogen and silicon molecules in the tetravinylsilane precursor 402 resulting in flowable silicon carbide film 406. As discussed further below, the flowable silicon carbide film 406 can be cured via the energy of the hydrogen radicals and/or exposure to UV light to form a cured silicon carbide film 408. Embodiments of the disclosure comprise curing via exposure to ultra-violet (UV) light and/or rapid thermal annealing.

FIG. 4B shows the reaction process 450 for forming a flowable silicon carbide layer using a trisilapentane precursor in accordance with some embodiments of the present disclosure. The trisilapentane precursor 452 is exposed to hydrogen radicals 454 from a hotwire source. Without intending to be bound by theory, the inventors of embodiments disclosed herein believe that the energy of the hydrogen radicals breaks the hydrogen-silicon bonds in the trisilapentane precursor 452 resulting in flowable silicon film 456. As discussed further below, the flowable silicon film 456 can be cured via the energy of the hydrogen radicals and/or exposure to UV light to form a cured silicon carbide film 458. Embodiments of the disclosure comprise curing via exposure to ultra-violet (UV) light and/or rapid thermal annealing to form a cured silicon carbide film 458.

FIG. 4C shows the reaction process 470 for forming a flowable silicon carbide layer using two precursor gases in accordance with some embodiments of the disclosure. The two precursor gases comprise at least one of silane, disilane, trisilane, tetrasilane, pentasilane, dodecachlorotetrasilane, or dodecachloropentasilane and at least one of methane, propane, tetravinylsilane or trisilapentane gas. The two precursor gases are decomposed by the hydrogen radical source in accordance with some embodiments of the present disclosure. As depicted, a trisilane precursor 472 and a methane gas are exposed to hydrogen radicals 476 from a hotwire source. Without intending to be bound by theory, the inventors of embodiments disclosed herein believe that the energy of the hydrogen radicals breaks the hydrogen-silicon bonds in the trisilane precursor 472 and methane 474, resulting in flowable silicon film 478. As discussed further below, the flowable silicon film 478 can be cured via the energy of the hydrogen radicals and/or exposure to UV light to form a cured silicon carbide film 480. Embodiments of the disclosure comprise curing via exposure to ultra-violet (UV) light and/or rapid thermal annealing to form a cured silicon carbide film 480.

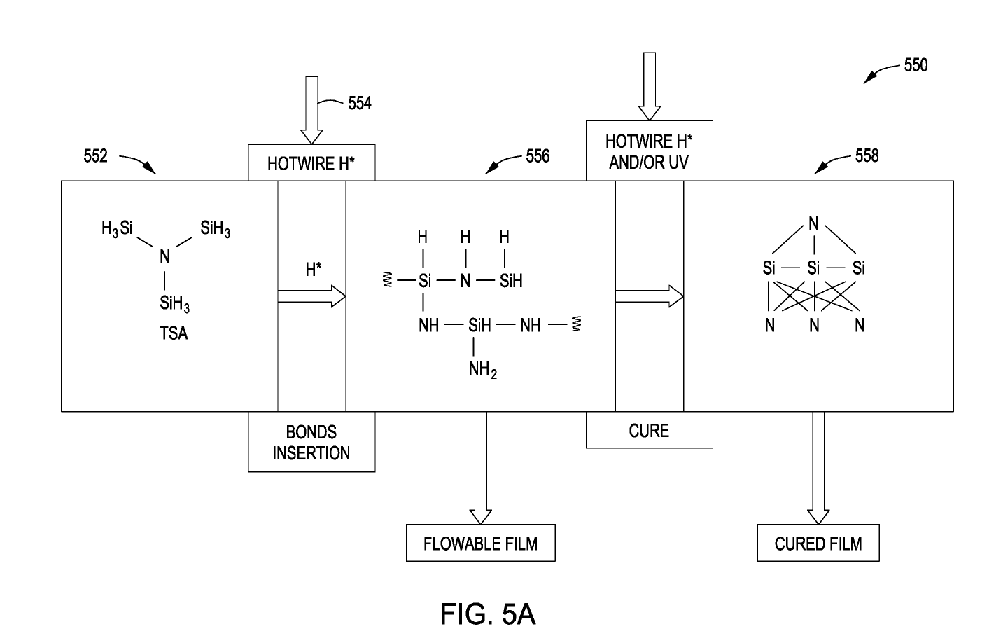

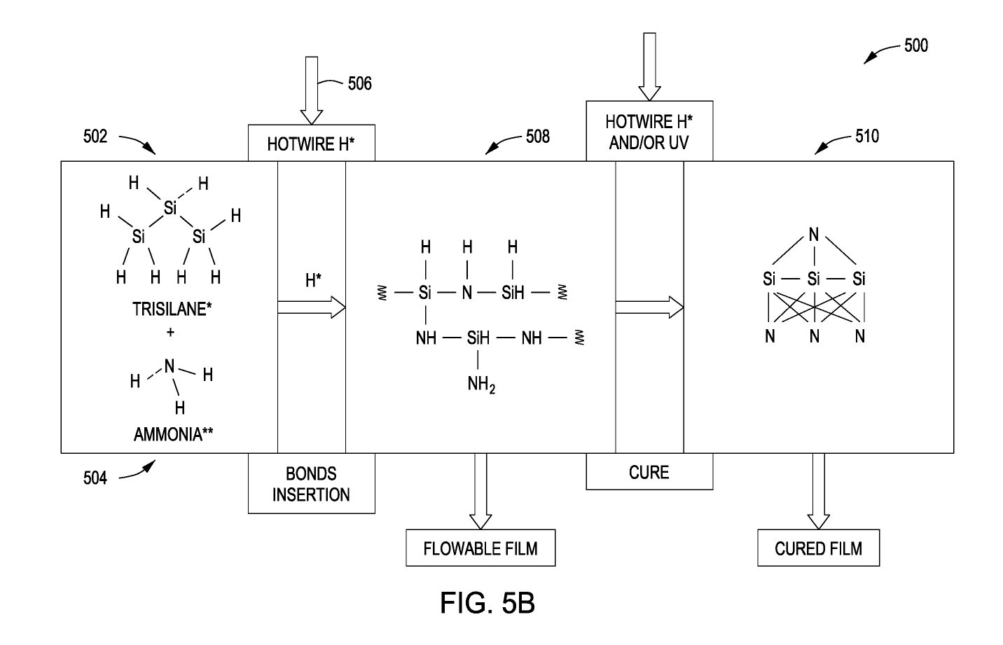

FIG. 5A shows the reaction process 550 for forming a flowable silicon nitride layer using a trisilylamine precursor. The trisilylamine precursor 552 is exposed to hydrogen radicals 554 from a hotwire source. Without intending to be bound by theory, inventors of embodiments disclosed herein believe that the energy of the hydrogen radicals breaks the hydrogen-silicon bonds in the trisilylamine precursor 552 resulting in flowable silicon nitride film 556. As discussed further below, the flowable silicon nitride film 556 can be cured via the energy of the hydrogen radicals and/or exposure to UV light to form a cured silicon nitride film 558. Embodiments of the disclosure comprise curing via exposure to ultra-violet (UV) light and/or rapid thermal annealing to form a cured silicon nitride film 558.

FIG. 5B shows the reaction process 500 for forming a flowable nitride layer using two precursor gases in accordance with some embodiments of the present disclosure. The two precursor gases comprise at least one of silane, disilane, trisilane tetrasilane, pentasilane, dodecachlorotetrasilane, or dodecachloropentasilane and/or at least one of trisilylamine, ammonia or nitrogen. The two precursor gases are decomposed by the hydrogen radical source in accordance with some embodiments of the present disclosure. As depicted, a trisilane precursor 502 and an ammonia gas 504 are exposed to hydrogen radicals 506 from a hotwire source. Without intending to be bound by theory, the inventors of embodiments disclosed herein believe that the energy of the hydrogen radicals breaks the hydrogen-silicon bonds in the trisilane precursor 502 and ammonia gas 504, resulting in flowable silicon nitride film 508. As discussed further below, the flowable silicon film 508 can be cured via the energy of the hydrogen radicals and/or exposure to UV light to form a cured silicon carbide film 510. Embodiments of the disclosure comprise curing via exposure to ultra-violet (UV) light and/or rapid thermal annealing to form a cured silicon carbide film 510.

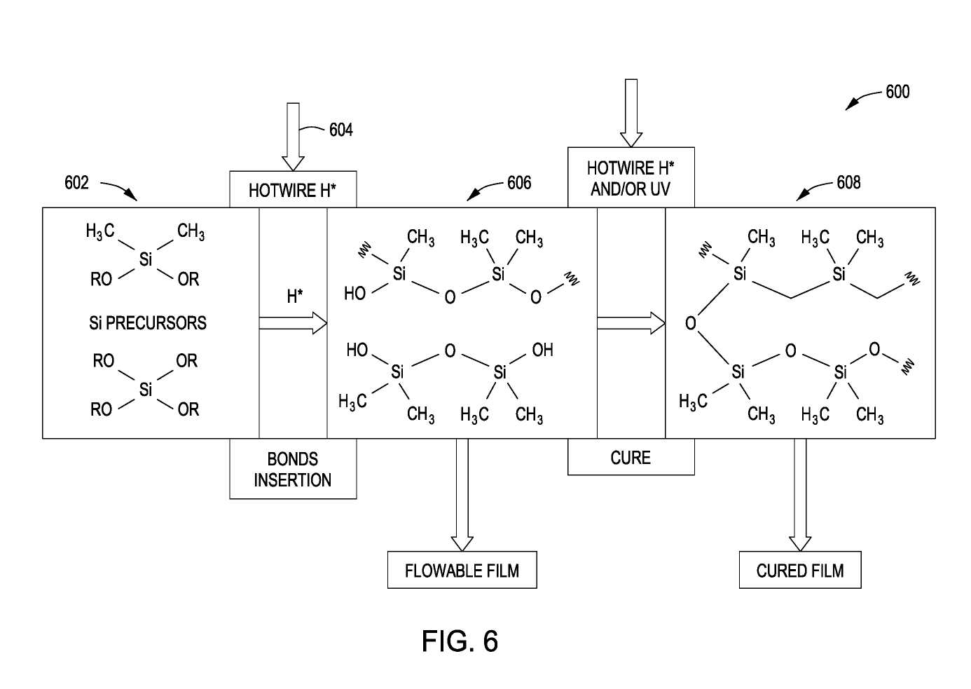

FIG. 6 shows the reaction process 600 for forming a flowable silicon oxycarbide layer using a tetramethoxysilane (TMOS), tetraethoxysilane (TEOS), trimethyloxysilane (TriMOS), triethoxysilane (TriEOS), tetramethyldisiloxane (TMDSO), hexamethoxydisilazoxane (HMDS-H) or octamethylcyclotetrasiloxane (OMCTS) precursor 602. The tetramethoxysilane, tetraethoxysilane, trimethyloxysilane, triethoxysilane, tetramethyldisiloxane, hexamethoxydisilazoxane, or octamethylcyclotetrasiloxane (OMCTS) precursor 602 is exposed to hydrogen radicals 604 from a hotwire source. Without intending to be limited by theory, the inventors of embodiments disclosed herein believe that the energy of the hydrogen radicals breaks the O—R bonds (oxygen-organic moiety bonds), initiating and allowing the TMOS, TEOS, TriMOS, TriEOS, TMDSO, HMDS-H, or OMCTS precursor 602 to polymerize, resulting in flowable silicon oxycarbide film 606. As discussed further below, the flowable silicon oxycarbide film 606 can be cured via the energy of the hydrogen radicals and/or exposure to UV light to form a cured silicon oxycarbide film 608. In FIG. 6, a TEOS precursor and a TMOS precursor are shown. TriMOS, TriEOS, TMDSO, HMDS-H, or OMCTS may be polymerized and deposited as a flowable silicon oxycarbide film 606.

The flowable silicon containing layer can be cured after depositing the flowable silicon containing layer. In some embodiments, the application of only UV light to the flowable silicon containing layer cures the flowable silicon containing layer. For example, in some embodiments, curing of the flowable silicon containing layer occurs with a chamber pressure of 5-500 torr and an exposure time of one to thirty minutes of ambient Ar at about 100-1000 sccm. In some embodiments, the flowable silicon containing layer is cured via application of hydrogen radical energy. For example, in some embodiments, a hydrogen gas flow of 5-500 sccm, a chamber pressure of 50 millitorr to 5 torr, and a filament temperature of 1300-2400° C. and an exposure time of about 10-600 seconds. In some embodiments, the flowable silicon containing layer is cured via application of hydrogen radical energy followed by application of UV light to the flowable silicon containing layer. Some embodiments comprise thermal annealing, for example, rapid thermal annealing to cure any film described herein. For some embodiments, it may be beneficial to utilize multiple curing steps such as combinations of rapid thermal annealing and/or UV curing techniques and processes.

In some embodiments, a first layer of the flowable silicon containing layer is formed on the substrate. The first layer can have a thickness that is less than the final thickness of the flowable silicon containing layer. For example, the first layer can have a thickness of about 10 to about 100 angstroms. The first layer can be cured via application of hydrogen radical energy followed by applying UV light to the flowable silicon containing layer. The process of depositing a first layer and then curing the first layer can be repeated until a flowable silicon containing layer having a predetermined thickness is formed. In some embodiments, after the flowable silicon containing layer having a predetermined thickness is formed, the flowable silicon containing layer having a predetermined thickness can be further cured by applying UV light to the flowable silicon containing layer having a predetermined thickness.

As described below with respect to FIG. 2, the HWCVD process chamber 226 comprises a plurality of wires 210. The plurality of wires 210 (or a plurality of filaments) is heated to a temperature suitable to dissociate the hydrogen gas, producing hydrogen ions that react with the precursor and deposit a silicon-containing film atop the substrate 230. For example, the plurality of wires 210 may be heated to a temperature of about 1300 to about 2400 degrees Celsius.

FIG. 2 depicts a schematic side view of an HWCVD process chamber 226 (i.e., process chamber 226) suitable for use in accordance with embodiments of the present disclosure. The process chamber 226 generally comprises a chamber body 202 having an internal processing volume 204. A plurality of wires 210 are disposed within the chamber body 202 (e.g., within the internal processing volume 204). The plurality of wires 210 may also be a single wire routed back and forth across the internal processing volume 204. The plurality of wires 210 comprises a HWCVD source. The plurality of wires 210 are typically made of tungsten. Tantalum, iridium or other high temperature conductors may also be used. For example, tantalum carbide (TaC), hafnium carbide (HfC), or tantalum hafnium carbide (TaHfC) may be used in embodiments of the disclosure. The wires 210 are clamped in place by support structures (not shown) to keep the wire taut when heated to high temperature, and to provide electrical contact to the wire. A power supply 212 is coupled to the wire 210 to provide current to heat the plurality of wires 210. A substrate 230 may be positioned under the HWCVD source (e.g., the plurality of wires 210), for example, on a substrate support 228. The substrate support 228 may be stationary for static deposition, or may move (as shown by arrow 205) for dynamic deposition as the substrate 230 passes under the HWCVD source.

The chamber body 202 further includes one or more gas inlets (one gas inlet 232 shown) to provide one or more process gases and one or more outlets (two outlets 234 shown) to a vacuum pump to maintain a suitable operating pressure within the process chamber 226 and to remove excess process gases and/or process byproducts. The gas inlet 232 may feed into a shower head 233 (as shown), or other suitable gas distribution element, to distribute the gas substantially uniformly over the plurality of wires 210.

In some embodiments, one or more shields 220 may be provided to minimize unwanted deposition on interior surfaces of the chamber body 202. Alternatively or in combination, one or more chamber liners 222 can be used to make cleaning easier. The use of shields, and liners, may preclude or reduce the use of undesirable cleaning gases, such as the greenhouse gas NF₃. The shields 220 and chamber liners 222 generally protect the interior surfaces of the chamber body from undesirably collecting deposited materials due to the process gases flowing in the chamber. The shields 220 and chamber liners 222 may be removable, replaceable, and/or cleanable. The shields 220 and chamber liners 222 may be configured to cover every area of the chamber body that could become coated, including but not limited to, around the wires 210 and on any or, optionally, all walls of the coating compartment. Typically, the shields 220 and chamber liners 222 may be fabricated from aluminum (Al) and may have a roughened surface to enhance adhesion of deposited materials (to prevent flaking off of deposited material). The shields 220 and chamber liners 222 may be mounted in the any or all areas of the process chamber, for example, around the HWCVD sources, in any suitable manner. In some embodiments, the source, shields, and liners may be removed for maintenance and cleaning by opening an upper portion of the deposition chamber. For example, in some embodiments, a lid, or a ceiling, of the deposition chamber may be coupled to the body of the deposition chamber along a flange 238 that supports the lid and provides a surface to secure the lid to the body of the deposition chamber.

A controller 206 may be coupled to various components of the process chamber 226 to control the operation thereof. Although schematically shown coupled to the process chamber 226, the controller may be operably connected to any component that may be controlled by the controller, such as the power supply 212, a gas supply (not shown) coupled to the gas inlet 232, a vacuum pump and/or throttle valve (not shown) coupled to the outlet 234, the substrate support 228, and the like, in order to control the HWCVD deposition process in accordance with the methods disclosed herein. The controller 206 generally comprises a central processing unit (CPU) 208, a memory 213, and support circuits 211 for the CPU 208. The controller 206 may control the process chamber 226 directly, or via other computers or controllers (not shown) associated with particular support system components. The controller 206 may be one of any form of general-purpose computer processor that can be used in an industrial setting for controlling various chambers and sub-processors. The memory, or computer-readable medium, 213 of the CPU 208 may be one or more of readily available memory such as random access memory (RAM), read only memory (ROM), floppy disk, hard disk, flash, or any other form of digital storage, local or remote. The support circuits 211 are coupled to the CPU 208 for supporting the processor in a conventional manner. These circuits include cache, power supplies, clock circuits, input/output circuitry and subsystems, and the like. Inventive methods as described herein may be stored in the memory 213 as software routine 214 that may be executed or invoked to turn the controller into a specific purpose controller to control the operation of the process chamber 226 in the manner described herein. For example, the memory 213 may be a non-transitory computer readable medium having instructions stored thereon that, when executed, cause the process chamber 226 to perform a method of processing a substrate disposed within a processing volume of a hot wire chemical vapor deposition (HWCVD) process chamber, as described herein. The software routine may also be stored and/or executed by a second CPU (not shown) that is remotely located from the hardware being controlled by the CPU 208.

While the foregoing is directed to embodiments of the present disclosure, other and further embodiments of the disclosure may be devised without departing from the basic scope thereof.

1. A method of processing a substrate disposed within a processing volume of a hot wire chemical vapor deposition (HWCVD) process chamber, comprising:
(a) providing a silicon containing precursor gas into the processing volume, the silicon containing precursor gas being provided into the processing volume from an inlet located a first distance above a surface of the substrate; and
(b) breaking hydrogen-silicon bonds within molecules of the silicon containing precursor gas via introduction of hydrogen radicals to the processing volume to deposit a flowable silicon containing layer atop the substrate, wherein the hydrogen radicals are formed by flowing a hydrogen containing gas over a plurality of wires disposed within the processing volume above the substrate and the inlet.

2. The method of claim 1, wherein the flowable silicon containing layer is at least one of pure silicon (Si), silicon oxycarbide (SiOC), silicon carbide (SiC), and silicon nitride (SiN).

3. The method of claim 2, wherein the flowable silicon containing layer is pure silicon (Si) and the silicon containing precursor gas is silane, disilane, trisilane, tetrasilane, pentasilane, dodecachlorotetrasilane, or dodecachloropentasilane.

4. The method of claim 2, wherein the flowable silicon containing layer is silicon oxycarbide (SiOC) and the silicon containing precursor gas is at least one of TEOS, TMOS, TriEOS, TriMOS, OMCTS, TMDSO, or HMDS-H.

5. The method of claim 2, wherein the flowable silicon containing layer is silicon carbide (SiC) and the silicon containing precursor gas is trisilapentane, tetravinylsilane, silane, disilane, trisilane, tetrasilane and at least one of methane or propane.

6. The method of claim 2, wherein the flowable silicon containing layer is silicon nitride (SiN) and the silicon containing precursor gas is trisilylamine or silane, disilane, trisilane, tetrasilane and at least one of ammonia and/or nitrogen gas.

7. The method of claim 1, wherein the first distance is about 10 to about 50 mm above the surface of the substrate.

8. The method of claim 1, wherein a temperature of the substrate is about 50 to about 150 degrees Celsius.

9. The method of claim 1, wherein a temperature of the plurality of wires is about 1300 to about 2400 degrees Celsius.

10. The method of claim 1, wherein a flow rate of the hydrogen containing gas is about 10 to about 1000 sccm.

11. The method of claim 1, wherein a flow rate of the silicon containing precursor gas is about 100 to about 1000 mg/min.

12. The method of claim 1, further comprising curing the flowable silicon containing layer after depositing the flowable silicon containing layer.

13. The method of claim 12, further comprising applying UV light and/or thermal annealing to the flowable silicon containing layer to cure the flowable silicon containing layer.

14. The method of claim 12, further comprising curing the flowable silicon containing layer via application of hydrogen radical energy.

15. The method of claim 12, further comprising curing the flowable silicon containing layer via application of hydrogen radical energy followed by applying UV and/or thermal annealing light to the flowable silicon containing layer.

16. The method of claim 1, further comprising:
(c) depositing a first layer of the flowable silicon containing layer;
(d) curing the first layer of the flowable silicon containing layer via application of hydrogen radical energy followed by applying UV light and/or thermal annealing to the flowable silicon containing layer; and
(e) repeating (c)-(d) to deposit the flowable silicon containing layer to a predetermined thickness.

17. The method of claim 16, further comprising:
(f) curing the flowable silicon containing layer deposited to a predetermined thickness via application of UV light and/or thermal annealing.

18. The method of claim 17, further comprising:
(f) curing the first layer of the flowable silicon containing layer via application of UV light and/or thermal annealing prior to repeating (c), (d), and (f).

19. A method of processing a substrate disposed within a processing volume of a hot wire chemical vapor deposition (HWCVD) process chamber, comprising:
(a) providing a silicon containing precursor gas into the processing volume, the silicon containing precursor gas being provided into the processing volume from an inlet located a first distance above a surface of the substrate;
(b) breaking hydrogen-silicon bonds within molecules of the silicon containing precursor gas via introduction of hydrogen radicals to the processing volume to deposit a flowable silicon containing layer atop the substrate, wherein the hydrogen radicals are formed by flowing a hydrogen containing gas over a plurality of wires disposed within the processing volume above the substrate and the inlet;
(c) depositing a first layer of the flowable silicon containing layer;
(d) curing the first layer of the flowable silicon containing layer via application of hydrogen radical energy followed by applying UV light and/or thermal annealing to the flowable silicon containing layer; and
(e) repeating (c)-(d) to deposit the flowable silicon containing layer to a predetermined thickness.

20. A non-transitory computer readable medium having instructions stored thereon that, when executed, cause a process chamber to perform a method of processing a substrate disposed within a processing volume of a hot wire chemical vapor deposition (HWCVD) process chamber, the method comprising:
(a) providing a silicon containing precursor gas into the processing volume, the silicon containing precursor gas being provided into the processing volume from an inlet located a first distance above a surface of the substrate; and
(b) breaking hydrogen-silicon bonds within molecules of the silicon containing precursor gas via introduction of hydrogen radicals to the processing volume to deposit a flowable silicon containing layer atop the substrate, wherein the hydrogen radicals are formed by flowing a hydrogen containing gas over a plurality of wires disposed within the processing volume above the substrate and the inlet, wherein the flowable silicon containing layer is at least one of pure silicon (Si), silicon oxycarbide (SiOC), silicon carbide (SiC), and silicon nitride (SiN).
